(19) United States
(12) Patent Application Publication
(10) Pub. No.: US 2004/0224182 A1
(43) Pub. Date: Nov. 11, 2004

(54) Backlight polar organic light-emitting device

(76) Inventor: Pavel I. Lazarev, Belmont, CA (US)

Correspondence Address: DORSEY & WHITNEY LLP, INTELLECTUAL PROPERTY DEPARTMENT, 4 EMBARCADERO CENTER, SUITE 3400, SAN FRANCISCO, CA, 94111, US

(21) Appl. No.: 10/643,257

(22) Filed: Aug. 18, 2003

Related U.S. Application Data
(60) Provisional application No. 60/438,714, filed on Jan. 7, 2003.

(51) Int. Cl. H05B 33/14; B05D 3/00

(52) U.S. Cl. 428/690; 428/917; 313/504; 313/506; 257/40; 427/66; 427/532

(57) ABSTRACT

An organic light-emitting device (OLED) is provided which comprises a substrate and an organic electroluminescent cell formed on the substrate. The organic electroluminescent cell comprises a first electrode that serves as an anode, a second electrode that serves as a cathode, and at least one light-emitting layer positioned between the anode and cathode. At least one light-emitting layer is an anisotropic electrically conducting layer which has a globally ordered crystalline structure and is comprised of rodlike supramolecules.

### RELATED APPLICATION

This application claims priority to the U.S. Provisional Patent Application No. 60/438,714 filed Jan. 7, 2003, the disclosure of which is hereby incorporated by reference in its entirety.

### FIELD OF THE INVENTION

The present invention relates generally to organic light-emitting devices, and more particularly to organic electroluminescent devices, which can be used as sources of polarized light.

### BACKGROUND OF THE INVENTION

Organic light-emitting devices (OLEDs) have attractive properties in their applications. OLEDs have a wide viewing angle, high rate of switching from one state to another, high luminance, wide color range, considerable lifetime, and relatively low cost. OLEDs are well compatible with electronic systems of display pixel control. OLEDs can serve as a base for developing alternative color display systems, with pixels representing electrically controlled display units.

An OLED includes several layers of various materials. See Tang et al., Appl. Phys. Lett., Vol. 51, 913 (1987). At least one layer is made of an organic compound. An OLED emits light under the influence of an applied electric voltage due to the electroluminescent properties of at least one material in the device.

The operation of an OLED is based on the general physical mechanisms of optical emission. One of such mechanisms involves the radioactive recombination of charge carriers, e.g., those captured by traps. As described above, an OLED contains at least two thin layers, at least one of which is made of an organic material. The anode and cathode electrodes connected to these layers serve as emitters of holes and electrons respectively. One of the aforementioned layers is made of a material which exhibits hole-conductivity, while the other layer possesses conductivity of the electron type. The electrode injecting holes (anode) is connected to the material with hole-conductivity, while the electrode injecting electrons (cathode) is in the contact with the material possessing electron conductivity. In this configuration, an OLED appears as a usual diode positively biased when a potential applied to the anode is higher than that applied to the cathode. With this polarity of the applied voltage, the anode injects holes into the layer possessing hole-conductivity, while the cathode injects electrons into the layer possessing electron conductivity. The injected carriers migrate toward opposite electrodes under the influence of internal electric field: electrons drift to the anode and holes to the cathode. It should be noted that electrons and holes localized in the same molecule form Frenkel excitons. Thus, an OLED represents a spatial zone featuring intensive recombination of electron-hole pairs (or excitons), which is called the electroluminescence (EL) zone. Recombination of an excited state, involving the transition of an electron from the corresponding excited energy level to the valence band during a short relaxation time, is accompanied by emission of a light quantum. Proceeding from this mechanism of operation of a thin-film OLED, we may conclude that charge carriers are supplied to the EL zone from both electrodes.

Frequently, only one layer in OLEDs, for example, the layer that possesses electron conductivity, is capable of the EL emission. Such devices are called single-heterojunction OLEDs. A typical single-heterojunction structure usually comprises a substrate, which can be either nontransparent or transparent, either flexible or hard, and can be made of plastic, metal, or glass. Alternatively, both electron transporting (n-type) and hole transporting (p-type) layers can be EL-active or doped with a special material possessing emissive properties and occurring at the interface between conducting layers. Devices of this type are called double-heterojunction OLEDs.

In an OLED, a transparent substrate supports a transparent conducting tin-doped indium oxide (ITO) layer, which serves as an anode. The anode layer is followed by a p-type layer and an n-type layer, above which a metal cathode is formed, for example, by vacuum deposition techniques. The structure is biased in an appropriate direction by applying a working voltage of certain polarity. The resulting internal electric field induces light emission in the OLED structure. The light beam is extracted from the device through the transparent ITO electrode and substrate layers. The metal cathode can function as a reflector.

A typical OLED can be implemented with a nontransparent substrate as well. There are known OLED structures, employing polymer EL-active films, which are formed on a nontransparent silicon substrate and provided with a semitransparent upper electrode (cathode) made of gold (Au) or aluminum (Al). Such devices emit light through the upper electrode.

Obviously, OLEDs can be readily integrated into an electronic system of display pixel control. In such integrated systems, the role of a substrate is performed by a nontransparent silicon plate. In these applications, it is convenient to employ OLEDs with the inverse sequence of layers. Such structures comprise a nontransparent substrate, followed by a metal cathode, a n-type layer, and a p-type layer. However, the formation of a transparent ITO electrode directly on a p-type layer may lead to degradation of the ITO layer. For this reason, a p-type layer should be covered with a protective layer, for example, a silicon dioxide layer, onto which the anode (ITO) can be applied. Evidently, the protective layer should be sufficiently thick to prevent the damaging influence of ITO on the p-type layer, while being sufficiently thin to provide the current transfer by tunneling through this layer. A disadvantage of the inverse structures with additional protective layers is the need of increasing the applied working voltage.

Another advantage of OLEDs is related to the fact that most organic films employed in such devices are transparent. See Gulovic et al., Transparent Organic Light Emitting Devices, Appl. Phys. Lett., Vol. 66, 2606 (1966). For this reason, it is possible to implement a principally new pixel design based on a vertical structure, whereby the OLED layers emitting red, green, and blue light are located one above another. This pixel design simplifies the assembly technology and allows at least a threefold decrease in the pixel size. The development of such transparent organic light emitting devices (TOLEDs) is a considerable progress in the technology of high-resolution liquid crystal displays. Such TOLEDs exhibit a high transmission (above 71%) in the turn-off regime and generate light with a high efficiency (quantum yield about 1%) in the turn-on regime. These TOLEDs employ transparent ITO electrodes injecting holes. The role of electron injectors in vertical structures is performed by Mg—Au electrodes. In the vertical TOLEDs, one electrode is formed at the bottom of the vertical structure and the other electrodes are arranged between OLEDs and on top of the structure. The bottom electrode is usually grounded, while the others are biased by positive or negative applied voltages. Each OLED in the vertical structure is controlled independently. Employing transparent contacts and glass substrates, such devices are capable of generating any color combination.

It is known that layers with hole (p-type) conductivity can be obtained using 3,4,9,10-pyrylenetetracarboxylic dianhydride (PTCDA), bis-(1,2,5-thiadiazolo)-p-quinobis-(1,3-dithiol) (BTQBT), and some other analogous compounds and their derivatives.

The layers possessing electron (n-type) conductivity can be made of aluminum tris (8-hydroxyquinoline) (Alq3). See Kepler et al., Electron and Hole Mobility in Tris-(8-hydroxyquinolinolato-N1, O8) Aluminum, Appl. Phys. Lett. Vol. 66, 3618 (1995).

Investigation of the characteristics of known OLEDs shows that it is desirable to increase the level of hole-injection in the device structure. See U.S. Pat. No. 5,998,803; Qui et al., Dependence of the Current and Power Efficiencies of Organic Light-Emitting Diodes on the Thickness of the Constituent Organic Layers, IEEE Trans. Electron Devices, Vol. ED-48, No. 9 (2001). It is found that a CuPc layer can serve as an effective hole-injector in usual OLEDs. Thus, there is a known OLED with a CuPc layer increasing the hole-injection, which is located between the p-type layer and the anode. See Qui et al., Room-Temperature Ultraviolet Emission from an Organic Light-Emitting Diode, Appl. Phys. Lett. Vol. 79, No. 14, 2276 (2001). The structure comprises a substrate, an anode, a hole-injection enhancer, a p-type layer, a n-type layer, a protective layer, and a cathode. It is known that the layer enhancing the hole-injection can be made of a perylene-based crystal. See U.S. Pat. No. 5,998,803.

Increased efficiency of a hole-injection is manifested by a higher value of the injected current at a preset direct bias voltage. Using a layer increasing the hole-injection level provides an increase of the injection current by at least 10%, while in typical cases the gain amounts to 50-100% as compared to analogous devices without the additional layer. It can be suggested that this layer ensures matching of the energy levels in the adjacent layers, thus enhancing the hole-injection. In other words, the additional level decreases the effective potential barrier for the carrier injection, thus increasing the efficiency of injection. It should be noted that a high value of the potential barrier creates the considerable obstacle for the injection, which is manifested by an increase in the turn-on voltage and a decrease in the light beam power.

U.S. Pat. No. 5,885,498 describes a known OLED, characterized by a high efficiency and a large working period, comprising a positive electrode (anode), a p-type layer, an a n-type layer, and a negative electrode (cathode). In this device, the light is emitted from a p-type layer made of an amorphous organic compound.

Thus, materials based on organic compounds, in particular, perylene and its derivatives, are used for obtaining (i) layers possessing hole (p-type) conductivity, (ii) layers (thin-film crystals) increasing the level of the hole-injection, and (iii) EL-active layers (amorphous) possessing p-type conductivity.

There are known methods of manufacturing thin layers for forming the multilayer structure of OLEDs.

The method of epitaxial formation of thin layers from large anisotropic organic molecules on inorganic substrates is known. The deposition process or mass transfer is conducted in a gas state such as vapor deposition in a vacuum chamber. The method of vapor-phase epitaxy forms layers of organic molecules on the substrates, made of graphite, alkali halide and other suitable materials. See: Uyeda et al., J. Appl. Phys. 43(12), 5181 (1972); Ashida, Bull. Chem. Soc. Jpn. 39(12), 2625-2631, 2632-2638 (1966); Saijo et al., J. Crystal Growth 40 118-124 (1977); Ashida et al., J. of Crystal Growth 8, 45-56 (1971); Murata et al., J. Microsc., 108(3), 261-275 (1976); Fryer, Acta Cryst. A35, 327-332 (1979); Ashida et al., Bull. Chem. Soc. Jpn. 39(12), 2616-2624 (1966); Saito et al., J. Crystal Growth 67, 91 (1984); and Saito et al, Appl. Surf. Sci. 22/23, 574-581 (1985).

There are known methods of epitaxial forming and polymerization of synthetic polymers and biopolymers on the substrates of alkali-halides from solutions, melts or a vapor-phase. For example, there is known use of inorganic minerals as substrates. See McPherson et al, J. Cryst. Growth 85, 206 (1988). U.S. Pat. No. 4,016,331 describes the method of vapor-phase epitaxial forming of thin organic films on thin substrates of thermoplastic polymer materials, which are made highly oriented by their elongation, heating or mechanical rubbing in one direction.

Some disadvantages of inorganic monocrystals limit their application as substrates for epitaxial forming of films. For example, only limited number of monocrystal substrate materials are known that are suitable for epitaxial forming so that the crystal surface of the substrate can be reactive, covered with oxides and/or contain water absorbing molecules. The substrate can be nontransparent for light, possess undesirable electron and/or thermal properties and so on.

There is known method of manufacturing the layer structure including a substrate, at least a part of at least one surface of which is covered by a first layer (“seed layer” or “orienting layer”) of crystal uniaxially oriented organic compounds and a second layer of crystal uniaxially oriented organic compounds formed on the first layer. See U.S. Pat. Nos. 4,940,854; 5,176,786 and EP 0352931. The second layer experiences the orienting influence of the first layer during the epitaxial formation. For short, the second layer is referred as an epitaxial layer. The organic compounds used in forming multilayer coverings according to the known method are polycyclic aromatic hydrocarbons and heterocyclic compounds. Polycyclic aromatic hydrocarbons and heterocyclic compounds are described in literature, see Morrison and Boyd, “Organic Chemistry”, Third Edition, Allyn and Bacon. Inc. (Boston, 1974). The polycyclic aromatic hydrocarbons used in the known method are naphthalenes, phenanthrenes, perylenes, anthracenes, coronenes and their derivatives. The heterocyclic aromatic compounds where the heteroatom is S, N, or O used in the known method are represented by phthalocyanines, porphyrins, carbazoles, pyrenes, pterins and their derivatives.

According to the known method, if the epitaxial layer of the organic compound is formed by the method of epitaxy from vapor (gas) phase on the orienting layer, then the crystal structure of the epitaxial layer will depend on the crystal structure of the orienting layer.

The reactor chamber used in the known method comprises two working zones, means for delivering buffer gases and means for creating vacuum inside the chamber (means of pumping out). Besides, inside the chamber, there are provided means for delivering buffer gases and means for maintaining a gradient of temperatures inside the reactor chamber between the working zones, with the temperature in the first working zone being higher than the temperature in the second one. The substrate is loaded in the second working zone and the source of organic compound is located in the first one. The chamber is pumped out until the pressure is in the range from 10⁻⁶ torr up to 10⁻¹⁰ torr. The chamber is then filled with the buffer gas and the pressure of the vapor of the buffer gas is maintained in the range from 0.001 torr to 10,000 torr. For transferring the organic compound from the source to the substrate, the temperature in the first working zone of the chamber is raised up to 400° C., which is enough for the vaporization of the organic compound and the temperature in the second working zone is lowed to the range between 20° C. and 100° C. During the entire process of forming the epitaxial film, the demanded temperature schedule and vacuum level should be maintained constant.

The temperature on the substrate can be any temperature but necessarily lower than that of the source. It is desirable that the temperature on the substrate is no more than 90% of the source temperature, but it is better, if this temperature is 25% or less of the temperature of the source.

In spite of the above advantages, the known methods have a number of disadvantages. In the prior art methods, in order to form the organic epitaxial layer with the necessary orientation of flat organic molecules and necessary crystallographic parameters, it is essential to form first the orienting layer on the substrate that in itself presents a difficult technical task. Further, physical (crystallographic) properties of the orienting layer and the orientation of flat molecules in orienting layer essentially depend on the temperature of the substrate during the process of the layer forming. There is its own allowable temperature range for each organic compound so the development of special technology is required for every compound.

In the prior art method, it is necessary to maintain the constant temperature and vacuum level in the reactor chamber during all the period of the epitaxial layer forming. Any deviations in temperature and in vacuum result in occurrence of defects in the epitaxial layer: the crystallographic parameters and orientation of molecular layers change. Such sensitivity to the instability of the technological parameters can also be attributed to the disadvantages of the known method. Especially this disadvantage is shown during formation of relatively thick epitaxial layers with the thickness from 1 to 10 micrometers.

The technological equipment used in the prior art methods are extremely complicated. It is essential that the prior art reactor chamber must bear high vacuum (up to 10⁻¹⁰ torr) and significant temperatures difference in very close located working zones. Besides, the technological equipments must comprise preheating systems, substrate cooling systems, complex pumping systems for achieving high vacuum, systems of delivering buffer gases, systems for monitoring temperature and pressure, and control systems for technological processes. It should be emphasized that the requirement of vacuum makes the process expensive and limits the sizes of substrates.

The disadvantage of the known method is also the fact that not any material can be used for manufacturing substrates. Only those materials which can maintain their physical, mechanical, optical and other properties under high vacuum, essential pressure drops and significant temperature differences can be used as substrates. Besides, the requirement of co-dimensional substrate and growing crystal lattices limits the range of compounds that are suitable for deposition.

The major disadvantage of vapor deposition is the strong influence of defects on the substrate surface on the structure of the forming layer. Deposition of molecules from vapor enhances/decorates defects on the substrate surface.

There is known method of layer (or film) deposition from solvents. See U.S. Pat. Nos. 5,646,284; 5,656,751; 5,710,273. This method is limited to solvable compounds and most of the solvents are highly hazardous liquids, which make manufacturing difficult and expensive. Also, coating is hindered by the low wet ability of the substrate surface.

Another method of thin crystal film (or thin crystal layer) manufacturing is known as the Optiva-Process. See U.S. Pat. Nos. 5,739,296 and 6,049,428, and P. Lazarev et al., “X-ray Diffraction by Large Area Organic Crystalline Nano-films”, Molecular Materials, 14 (4), 303-311 (2001), and Bobrov, “Spectral Properties of Thin Crystal Film Polarizers”, Molecular Materials, 14 (3), 191-203 (2001). This process involves a chemical modification step and four steps of ordering during the crystal film formation. This multistage process is hereafter referred as Cascade Crystallization Process. The chemical modification step delivers ionogenic (hydrophilic) groups on the periphery of the molecule in order to impart amphiphilic properties to the molecule. Amphiphilic molecules stack together in super molecules, which is the first step of ordering. By choosing characteristic concentration, super molecules are converted into a liquid-crystalline state to form a lyotropic liquid crystal, which is the second step of ordering. The lyotropic liquid crystal is deposited under the influence of a shear force (or meniscus force) onto a substrate, so that the shear force (or the meniscus) direction determines the crystal axis direction in the resulting solid crystal film. This shear-force-assisted directional deposition is the third step of ordering, representing the global ordering of the crystalline or polycrystalline structure on the substrate surface. The last fourth step of the Cascade Crystallization Process is the drying/crystallization, which converts the lyotropic liquid crystal into a solid crystal film. In this application, the term Cascade Crystallizatioh Process is used to describe the chemical modification and four ordering steps as a combined process.

The layer produced by this method has a global order. The global order means that the direction of the crystallographic axis of the layer over the entire substrate surface is controlled by the deposition process and, with a limited influence of the substrate surface. The major advantage of the Cascade Crystallization Process is the weak dependence of the layer on the surface defects. This weak dependence is due to the viscous and elastic properties of the lyotropic liquid crystal. The elastic layer of a liquid crystal prevents the development of the defect field and inhibits defect penetration into the bulk of the deposited layer. Elasticity of the lyotropic liquid crystal acts against reorientation of the molecules under the influence of the defect field. Molecules of the deposited material are packed into lateral super molecules with a limited freedom of diffusion or motion.

The anisotropic crystalline layer can also be formed through extrusion of a lyotropic liquid crystal by an extruder.

A disadvantage of this method is the presence of sulfate/sulfite groups in the resulting layer. The presence of such hydrophilic groups interfere the electronic properties of the crystal layer. Hydrophilic groups change the optical and electronic properties of the material.

### SUMMARY OF THE INVENTION

The present invention provides a method of making an anisotropic electrically conducting layer, which has a globally ordered crystalline structure. According to the method of the invention, an anisotropic crystalline layer is formed by means of Cascade Crystallization Process. The anisotropic crystalline layer is characterized by the globally ordered crystalline structure with intermolecular spacing of 3.4±0.3 Å along the polarization axis of the layer, and formed by rodlike supramolecules, which comprise at least one polycyclic organic compound with conjugated π-system and ionogenic groups. An external influence is subsequently applied upon the formed anisotropic crystalline layer to remove the ionogenic group from the anisotropic crystalline layer. The duration, character and intensity of the external influence are selected so as to ensure a partial removal of the ionogenic groups from the anisotropic crystalline layer while retaining a crystalline structure after termination of the external influence.

The present invention further provides an organic light-emitting device (OLED). The OLED comprises a substrate and an organic electroluminescent cell formed on the substrate. The organic electroluminescent cell comprises a first electrode that serves as an anode, a second electrode that serves as a cathode, and at least one light-emitting layer located between the anode and cathode. The light-emitting layer is an anisotropic electrically conducting layer, which has a globally ordered crystalline structure with an intermolecular spacing of 3.4±0.3 Å in the direction of one of optical axes. The light-emitting layer is comprised of rodlike supramolecules, which comprise at least one polycyclic organic compound with conjugated π-system.

### BRIEF DESCRIPTION OF THE DRAWINGS

The present invention will be better understood upon reading of the following description and claims accompanied by the drawings in which:

FIG. 1 shows the data of derivatographic analysis (the weight loss).

FIG. 2 is a schematic showing an organic light-emitting device comprising an light-emitting layer in accordance with one embodiment of the present invention.

FIG. 3 is a schematic showing an organic light-emitting device which additionally comprises an electron transporting layer and a hole transporting layer in accordance with one embodiment of the present invention.

FIG. 4 is a schematic showing an organic light-emitting device which additionally comprises a highly absorbing and low reflective layer in accordance with one embodiment of the present invention.

FIG. 5 is a schematic showing an organic light-emitting device which additionally comprises an inorganic resistive layer in accordance with one embodiment of the present invention.

FIG. 6 is a schematic showing an organic light-emitting device which additionally comprises a bi-layer interfacial structure in accordance with one embodiment of the present invention.

FIG. 7 is a schematic showing an organic light-emitting device which additionally comprises a hole-injecting enhancement layer in accordance with one embodiment of the present invention.

### DETAIL DESCRIPTION OF THE INVENTION

As used in the description of this application, the following terms have the following meanings:

“Bottom electrode” refers to an electrode that is deposited directly onto the substrate.

“Top electrode” refers to an electrode that is deposited atop an organic electroluminescent cell and distal to the substrate.

“Hole-injection layer” refers to a layer into which holes are injected from an anode when a voltage is applied to an organic electroluminescent cell.

“Hole-transport layer” refers to a layer having high hole-mobility and high affinity for holes that is between the anode and the emitter layer. It will be evident to those skilled in the art that the hole-injection layer and the hole-transport layer can be a single layer, or they can be distinct layers comprising different chemical compounds.

“Electron-injection layer” refers to a layer into which electrons are injected from a cathode when a voltage is applied to an OLED.

“Electron-transport layer” refers to a layer having high electron mobility and high affinity for electrons that is between the cathode and the emitter layer. It will be evident to those skilled in the art that the electron-injection layer and the electron-transport layer can be a single layer, or they can be distinct layers comprising different chemical compounds.

The present invention provides a method of making an anisotropic electrically conducting layer which has a globally ordered crystalline structure. According to the method of the invention, an anisotropic crystalline layer is formed by means of Cascade Crystallization Process. The anisotropic crystalline layer is characterized by the globally ordered crystalline structure with intermolecular spacing of 3.4±0.3 Å along the polarization axis of said layer, and formed by rodlike supramolecules, which comprise at least one polycyclic organic compound with conjugated π-system and ionogenic groups. An external influence is subsequently applied upon the formed anisotropic crystalline layer to remove the ionogenic group from the anisotropic crystalline layer. The duration, character and intensity of the external influence are selected so as to ensure a partial removal of the ionogenic groups from the anisotropic crystalline layer while retaining a crystalline structure after termination of the external influence.

The anisotropic crystalline layer can also be formed through extrusion of a lyotropic liquid crystal by an extruder.

The anisotropic crystalline layer produced by this method has a global order or in other words such layer has a globally ordered crystalline structure. The global order means that the direction of the crystallographic axis of the anisotropic crystalline layer over the entire substrate surface is controlled by the deposition process. The external influence, which is applied upon the formed anisotropic crystalline layer, does not disturb the global order of this layer. Thus, the anisotropic crystalline layer differs from a polycrystalline layer, in which the uniform crystalline structure is formed inside a separate crystallite. The square of such crystallite is much less than square of the substrate. Also in the discussed anisotropic crystalline layer, the limited influence of the substrate surface on its crystalline structure takes place. The anisotropic crystalline layer can be formed on a part of the surface of the substrate or on the entire surface depending in the requirements. In both cases the anisotropic crystalline layer is characterized by the global order.

There is a known method for forming anisotropic crystalline layers using a lyotropic liquid crystal of at least one organic compound. See U.S. Pat. Nos. 5,739,296 and 6,049,428, and P. Lazarev, et al., “X-ray Diffraction by Large Area Organic Crystalline Nano-Films”, Molecular Materials, 14(4), 303-311 (2001); Y. Bobrov, “Spectral properties of Thin Crystal Film Polarizers” Molecular Materials, 14(3), 191-203 (2001). The method is simple and economically effective, and ensures a high degree of anisotropy and crystallinity of the layers, offers the possibility of obtaining thin crystal films of arbitrary shape including multi-layer coatings on curvilinear surfaces, and is ecologically safe, labor and energy saving. Using the known method, it is also possible to obtain single crystal films.

This known method for forming an anisotropic crystalline layer, hereafter referred to “Cascade Crystallization Process”, is characterized by the following sequence of technological operations:

(1) Chemical modification of the target compound;

(2) Formation of a lyotropic liquid crystal;

(3) Application of the lyotropic liquid crystal of at least one organic compound onto a substrate;

(4) External liquefying influence upon the lyotropic liquid crystal in order to decrease its viscosity;

(5) External aligning the influence upon the lyotropic liquid crystal in order to impart a predominant orientation to particles of the colloid solution;

(6) Termination of the external liquefying influence and/or application of an additional external influence so as to restore the lyotropic liquid crystal viscosity on at least the initial level; and

(7) Drying.

Upon completing the above operations, the Cascade Crystallization Process produces anisotropic crystalline layers with an intermolecular spacing of 3.4±0.3 Å in the direction of one of the axes.

The ionogenic (hydrophilic) groups can be sulfonic groups, COO⁻, PO₄⁻, cation groups, and carboxy groups, etc. The ionogenic groups are used to impart amphiphilic properties to the initial organic substances.

The external influence upon the anisotropic crystalline layer is applied by local or complete heating of the crystalline layer up to the pyrolysis temperature. The pyrolysis temperature is characteristic for each organic compound and can be experimentally determined. As used in the description, the term “pyrolysis temperature” refers to the temperature at which the ionogenic group is destructed and broken off.

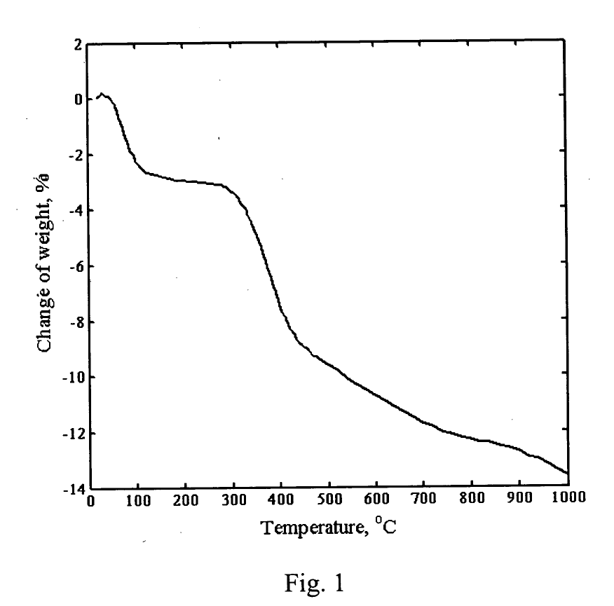

More precisely, the temperature of pyrolysis can be defined on the basis of data of derivatographic analysis. The data of derivatographic analyses (the weight loss) are shown in FIG. 1. FIG. 1 presents the thermo-analytical curves showing the change of the sample weight in the course of heating of a sample of indanthrone. The temperature was increased from ambient temperature (21.6° C.) up to 1000° C. with constant speed of increase of temperature, which was equal to 4.9-5 degrees per minute. The derivatographic analysis or the analysis of temperature dependence of weight loss of organic compound sample as a result of removing from them the sulfonic, sulfate or sulfite groups has shown, that pyrolysis temperature in this case is in the range between 330° C. and 350° C. The removing of ionogenic groups is confirmed by detecting their solubility in polar solvents. The solubility of such samples decreases after their thermal processing in the indicated temperature range.

The heating of the anisotropic crystalline layer in this method can be carried out by various ways, for example, by utilizing concentric electrical heaters and/or microwave radiation, and/or resistive heaters, and/or alternative electric or magnetic field, and/or a flow of heated liquids and/or gases. The heating can be conducted both from the side of the substrate and from the side of the formed crystal film. It is also possible to carry out the heating simultaneously from both specified sides.

Pyrolysis of the anisotropic crystalline layer increases the mechanical hardness and improves the adhesion of the layer to the substrate.

The break off of ionogenic groups, in particular, sulfogroups, can be achieved if the external influence is carried out by a microwave and/or the laser radiation. The frequency, intensity and duration of the influence is chosen so as to ensure a partial removal of a part of the ionogenic groups are removed from the anisotropic crystalline layer while retaining the crystal structure of the layer. The radiation frequency (or the corresponding photon energy) is selected so as to be in resonance with at least one absorption band of the organic compound (the energy of binding of the ionogenic groups). The frequency of radiation (or the energy of corresponding photons) should be such that the break off of ionogenic groups are not accompanied by the distraction of other bonds in the initial organic compound. The radiation frequency and the duration of the external influence are selected experimentally for each initial organic compound. Thus, the frequency, intensity and duration of radiation should be selected to make possible the removal of sulfogroups or any other ionogenic (hydrophilic) groups (e.g., COO⁻, PO4⁻, cationic groups, carboxy groups and others), which provide amphiphilic properties for the initial organic compound.

The above mentioned ionogenic groups, especially sulfogroups, are very effective traps for the active charge carriers (electrons and/or holes) in the material of the anisotropic crystalline layer. Therefore, the removal of such groups results in increase of the electron and hole activity and consequently increase of the electro conductivity of the anisotropic crystalline layer.

In a possible embodiment of the disclosed method, a layer of electrically conducting material is additionally formed on the substrate and then an anisotropic crystalline layer is formed on this electrically conducting layer. In another possible variant of the disclosed method, at least one anisotropic electrically conducting layer is previously formed on the substrate and then an anisotropic crystalline layer is formed on these anisotropic electrically conducting layers.

The external influence on the anisotropic crystalline layer can be carried out in a buffer gas or an inert gas atmosphere such as He, Ar, Xe, and other non-reactive gases such as nitrogen and CO₂. The listed gases are given as possible examples and are not intended to limit the choice of other analogous gases and compounds.

The present method can provide anisotropic electrically conducting layers with useful electrical and optical properties. For this purpose the initial organic compound can additionally contain at least one dopant and/or compound which does not break the flat structure of the molecule or a fragment of the molecule of the lyotropic liquid crystal organic substance and changes the type and size of the electrical conductivity of the formed anisotropic electrically conducting layer. The dopant and/or compound can be a donor mixture that promotes the formation of the anisotropic electrically conducting layer with the electron type conductivity or can be an acceptor mixture that promotes the formation of the anisotropic electrically conducting layer with the hole-type conductivity. Besides, dopants added to the initial organic substance can change the dynamical properties of the active charge carriers-electrons and holes. By choosing correspondent dopants and compounds, the drift activity of both electrons and holes in the external electric fields can be increased. Dopants and/or compounds can also change the light emitting properties of the anisotropic electrically conducting layers. Thus, the mentioned dopants and/or compounds can create centers of emitting electron-hole recombination in the anisotropic electrically conducting layer with the emission of quantums of light in infra red and/or visible and/or ultraviolet parts of the spectrum.

In one embodiment of the disclosed method, the organic compound used for preparing a lyotropic liquid crystal includes at least one aromatic compound with the general structural formula {K}(M)n, where K is a dye, the structure of which contains one or more ionogenic groups, either same or different, ensuring the solubility in polar solvents for the formation of a lyotropic liquid crystal phase; M is a counterion; and n is the number of counterions in the dye molecule, which can be fractional if the counterion is shared among several molecules.

The present invention further provides an organic light-emitting device (OLED). In general, the OLED comprises a substrate and an organic electroluminescent cell formed on the substrate. The organic electroluminescent cell comprises a first electrode that serves as an anode, a second electrode that serves as a cathode, and at least one light-emitting layer located between the anode and cathode. The at least one light-emitting layer is an anisotropic electrically conducting layer, which has a globally ordered crystalline structure with an intermolecular spacing of 3.4±0.3 Å in the direction of one of optical axes. The light-emitting layer is comprised of rodlike supramolecules, which comprise at least one polycyclic organic compound with conjugated π-system. The disclosed organic light-emitting device is a source of a polarized light and can be utilized for backlight in liquid crystal displays.

The single or double heterostructural OLEDs are provided as examples to illustrate how an OLED embodying the present invention may be fabricated without intention to limit the invention to the particular sequence or order of making the layers shown. For example, a single heterostructural OLED of the invention includes a flexible substrate, which is preferably transparent, a first electrode, which is typically an indium tin oxide (ITO) anode layer, a hole transporting layer, an electron transporting layer, a second electrode layer, for example, a metal cathode layer of Mg/Ag, and a metal protective layer, for example, made of a layer of Ag, for protecting the Mg/Ag cathode layer from atmospheric oxidation. A double heterostructure additionally include a layer containing an emissive material. This additional layer is hereafter referred to as a “separate emissive layer” so as to distinguish it from the other layers, since the hole transporting layer and electron transporting layer can be made to produce electroluminescent emission without the need for this separate emissive layer.

In one embodiment an OLED comprises a bottom electrode, which is either an anode or a cathode, a top electrode, which is a cathode if the bottom electrode is an anode and which is an anode if the bottom electrode is a cathode, and an electroluminescent medium having at least two layers, one comprising at least one hole-injection/hole-transport material that is adjacent to the anode and the other comprising at least one electron-injection/electron-transport layer that is adjacent to the cathode.

In another embodiment, the top electrode is the cathode and the bottom electrode, which is deposited directly onto the substrate, is the anode. Between the cathode and the anode is an electron-injection/electron-transport layer adjacent to the cathode and a hole-injection/hole-transport layer adjacent to the anode.

In another embodiment, the top electrode is the anode and the bottom electrode, which is deposited directly onto the substrate, is the cathode. Between the cathode and the anode is a hole-injection/hole-transport layer adjacent to the anode and an electron-injection/electron-transport layer adjacent to the cathode.

In a further embodiment, the top electrode is the cathode and the bottom electrode, which is deposited directly onto the substrate, is the anode. The OLED further comprises an electron-transport layer adjacent to the cathode, a hole-injection/hole-transport layer comprising a hole-injection layer adjacent to the anode and at least one hole-transport layer adjacent to the hole-injection layer. Between the electron-transport layer and the hole-transport layer, the OLED further comprises an emitter layer wherein holes and electrons recombine to produce light.

In another embodiment, the OLED comprises a hole-injection layer adjacent to the anode and at least two hole-transport layers, a first hole-transport layer adjacent to the hole-injection layer and the second hole-transport layer adjacent to the first hole-transport layer.

In one embodiment, the hole-injection layer and the at least two hole-transport layers are deposited separately.

In one embodiment, the OLED comprises an electron-injection layer and at least one electron-transport layer.

In one embodiment, the electroluminescent medium comprises a hole-injection/hole-transport layer adjacent to the anode, an electron-injection/electron-transport layer adjacent to the cathode, and an emitter layer between the hole-injection/hole-transport layer and the electron-injection/electron-transport layer.

In another embodiment, the OLED can further comprise an additional layer adjacent to the top electrode. In a preferred embodiment, the layer comprises indium tin oxide.

Other OLED structures will be evident to those skilled in the art.

In one embodiment, a typical OLED is formed by starting with a semi-transparent bottom electrode deposited on a glass substrate. In one embodiment, the electrode is an anode. In another embodiment, the electrode is a cathode. In another embodiment, the top electrode is semi-transparent.

An anode is typically about 800 Å thick and can have one layer comprising a metal having a high work function, a metal oxide and mixtures thereof. Preferably, the anode comprises a material selected from the group consisting of a conducting or semiconducting metal oxide or a mixed metal oxide such as indium zinc tin oxide, indium zinc oxide, ruthenium dioxide, molybdenum oxide, nickel oxide or indium tin oxide, a metal having a high work function, such as gold or platinum, and a mixture of a metal oxide and a metal having a high work function. In one embodiment, the anode further comprises a thin layer (approximately 5-15 Å thick) of dielectric material between the anode and the first hole-injection/hole-transport layer. Examples of such dielectric materials include, but are not limited to, lithium fluoride, cesium fluoride, silicon oxide and silicon dioxide. In another embodiment, the anode comprises a thin layer of an organic conducting material adjacent to the hole-injection/hole-transport layer. Such organic conducting materials include, but are not limited to, polyaniline, PEDOT-PSS, and a conducting or semi-conducting organic salt thereof.

A semi-transparent cathode is typically between 70 and 150 Å thick. In one embodiment, the cathode comprises a single layer of one or more metals, at least one of which has a low work function. Such metals include, but are not limited to, lithium, aluminum, magnesium, calcium, samarium, cesium and mixtures thereof. Preferably, the low work function metal is mixed with a binder metal, such as silver or indium. In another embodiment, the cathode further comprises a layer of dielectric material adjacent to the electron-injection/electron-transport layer, the dielectric material including, but not limited to, lithium fluoride, cesium fluoride, lithium chloride and cesium chloride. Preferably, the dielectric material is lithium fluoride or cesium fluoride. In preferred embodiments, the cathode comprises aluminum and lithium fluoride, a mixture of magnesium and silver, or a mixture of lithium and aluminum. In one else embodiment, the cathode comprises magnesium, silver and lithium fluoride.

In one embodiment, the OLED comprises an emitter layer between the electron-injection/electron-transport layer and the hole-injection/hole-transport layer in which electrons from the electron-injection/electron-transport layer and holes from the hole-injection/hole-transport layer recombine. Depending on the composition of the emitter layer, OLEDs emit visible light of different colors. Emitter layers typically comprise at least one host compound, either alone or together with at least one dopant compound.

An emitter layer may be between 200-400 Å thick.

In one embodiment, the organic light-emitting device comprises at least one layer of at least one organic electroluminescent cell which can be simultaneously electron transporting and light emitting. In another embodiment, the organic light-emitting device comprises at least one layer of at least one organic electroluminescent cell which is simultaneously hole-transporting and light emitting. In a further embodiment, the organic light-emitting device comprises at least one layer of at least one organic electroluminescent cell which is simultaneously light-emitting and both electron- and hole-transporting.

In one embodiment, the organic light-emitting device comprises at least an organic electroluminescent cell which additionally contains at least one electron transporting layer, located between the cathode and the light-emitting layer and/or at least one hole transporting layer, located between the anode and the light-emitting layer.

The organic light-emitting device can also use organic compounds which are widely utilized in different solar cells, OLEDs and other photovoltaic devices. Thus, at least one light-emitting layer of the organic electroluminescent cell can be formed using either indanthrone (Vat Blue 4), or 1,4,5,8-naphtalene tetracarboxylic dibenzoimidazol (Vat Red 14), or 3,4,9,10-pyrylentetracarboxylic dibenzoimidazol, or hinacridon (Pigment Violet 19) or 3,4,9,10-pyrylenetetracarboxylic dianhydride (PTCDA) or bis-(1,2,5-thiadiazolo)-p-quinobis-(1,3-dithiol) (BTQBT) or aluminum tris (8-hydroxyquinoline) (Alq3).

The lyotropic liquid crystal for making at least one light-emitting layer of the organic electroluminescent cell can be also prepared based on various phthalocyanines, such as metal-free phthalocyanine (H₂Pc), phthalocyanines with monovalent or divalent metal (such as Li₂Pc, MgPc), phthalocyanines with metal halide or metal hydroxide (such as AlClPc, AlOHPc), phthalocyanines with tetravalent metals (TiOPc, SiCl₂Pc, Si(OH)₂Pc), or phthalocyanines in which the central ion of metal is replaced or substituted at the phthalocyanine ring by such as sulfonic acid (or amide), carboxylic acid, alkyl, aryl, halide, nitro, etc. Other phthalocyanines can also be used such as VOPc, CrPc, FePc, CoPc, NiPc, CuPc, ZnPc, SnCl₂Pc, PbPc, Ge(OH)₂Pc, InBrPc, and so on, or their mixtures.

At least one light-emitting layer of the organic electroluminescent cell can be formed with the use of different pigments or 3,3′-dichlorobenzidine or 2,7-diaminofluorenone, or 2,6-diaminoanthraquinone, or 2,7-diaminoanthraquinone, or (p-aminophenyl) phenylamine, or tris (p-aminophenyl) amine, or 2,7-diaminodibenzothiophene sulfone, or 2,7-diaminodibenzothiophene, or 2-(p-aminophenyl)-6-aminobenzoxazole, or bis (p-aminophenyl) amine, or N-methylbis (p-aminophenyl) amine, or 2,5-bis (p-aminophenyl)-1,3,4-oxadiazole, or 1,6-diaminopyrene, or 1,5-diaminonaphthalene, or some other analogous organic compounds and their mixtures. For effectiveness of the organic light-emitting device, it is preferred to use organic substances with high hole activity. The hole transporting layers can be formed from such substances in the present organic light-emitting device. For this purpose at least one hole transporting layer of the organic electroluminescent cell can be formed with the use of triphenylamine tetramer as the main component of the mixture and 5,6,11,12-tetraphenylnaphthacene or 9,10-diphenylanthracene as the addition in the amount of 0.1-10%. 4,4′-bis-[(1-naphthyl)-N-phenylamino]-bi-phenyl or N,N′-diphenyl-N,N′-bis (3-methylpheny) 1-1′biphenyl-4,4′diamine can also be used for the forming of at least one hole transporting layer of the organic electroluminescent cell.

The material of at least one hole transporting layer of the organic electroluminescent cell can be also preferably selected from the group consisting of aromatic tertiary amines. For the effectiveness of the organic light-emitting device, it is preferred to use the materials with high electron activity. The electron transporting layers are formed from such materials. The organic compounds, widely used in photovoltaic devices can be used in the present organic light-emitting device. At least one electron transporting layer of the organic electroluminescent cell can be formed with the use of tris-(8-quinolinato-N1, O8)-aluminum or copper phthalocyanine (CuPc) or zinc oxide (ZnO1-x).

It is preferably to use effective electron injectors in the present organic light-emitting device. For this purpose at least one electrode (cathode) should be made of a material with small work function of electrons and should be used in the electroluminescent cell for electron injection. In the present organic light-emitting device, at least one electrode can be nontransparent and can be made of aluminum or silver or gold or alloys of Ca/Al or Mg/Ag or Li/Al or other suitable metals and their alloys. It is also important that the organic light-emitting devices have a highly effective hole-injector. Thus it is preferred that at least one electrode (anode) is made of a material with large work function of electrons and is used in the electroluminescent cell for injection of holes. Such embodiment of the organic light-emitting device is possible in which at least one electrode is transparent and is of ITO.

Without any limitation to the present invention regarding the thickness ranges recited herein, the thickness of the ITO anode layer can be from about 1000 Å (1 Å=10⁻⁸ cm) to greater than about 4000 Å. The thickness of the hole transporting layer can be about 50 Å to greater than about 1000 Å. The thickness of the emissive material containing layer can be about 50 Å to about 200 Å. The thickness of the electron transporting layer can be about 50 Å to about 1000 Å. The thickness of each metal layer can be about 50 Å to greater than about 100 Å, or substantially thicker if the cathode layer is not intended to be transparent.

The substrates of different forms made from different organic and inorganic substances can be used in the present organic light-emitting device. At least one substrate can be transparent or nontransparent, hard or flexible, made of glass or of quartz, plastic or metal or a semiconductor. Besides, at least one substrate can have a flat, or convex or concave or varied form of surface. At least one substrate has anisotropic properties, at least on the part of the surface, which are caused by either chemical bonds, or the relief or the texture formed on the. surface of the substrate either from the material of the substrate itself or from the material applied on the surface of the substrate. Different metals can be used as the substrates. At least one substrate can be made of aluminum, or cobalt, copper, molybdenum, nickel, platinum, tantalum, or other metals and their alloys. It is also possible that at least one substrate can be made of polymer substances or glass, metals, ceramics, metal ceramics or other analogous materials and their different combinations.

In order to increase the contrast ratio of the organic light-emitting device, at least one organic electroluminescent cell can additionally contain a highly absorbing and low reflective layer, located between the cathode and organic electron-transporting layer. At least one highly absorbing and low reflective layer can be made of electrically conductive materials having a work function less than 4.0 eV, and being substantially black in bulk form, for example, of calcium hexaboride (CaB₆) and/or lanthanum nitride (LaN) and/or zinc oxide (ZnO). While such highly absorbing and low reflective layers are used, the light from the external sources is absorbed inside the offered organic light emitting device, which leads to the increase of the contrast ratio.

For forming organic light-emitting device, thin organic hole transporting layers are used. Porous sites can be formed in such thin layers, during its forming. In that case current-conducting canals can be formed in the thin hole transporting layer that will result in irregular distribution of a current in the multilayer structure of the offered organic light-emitting device. The non-uniformity of the current can lead to local hasp and/or local overheating of the multilayer structure. It should be mentioned that these effects result in reduction of term of trouble-free work of the device. Accordingly, in one embodiment, at least one organic electroluminescent cell of the organic light-emitting device additionally contains an inorganic resistive layer, located between the anode and organic hole transporting layer. Different inorganic materials can be used for forming inorganic resistive layer. In another embodiment, the present device contains at least one inorganic resistive layer which is formed of amorphous silicon or amorphous indium/tin oxide or amorphous indium/zirconium oxide or of other type of the thin film resistive layer which sheet resistance is between 10³ ohms/cm² to 10⁸ ohms/cm².

For the effectiveness of the present organic light-emitting device, it is preferred to use materials with high concentration of centers of emitting electron-hole recombination for manufacturing light-emitting layers. Thus in one embodiment, the present device can use light-emitting materials, which are widely utilized in photovoltaic devices. Thus, such embodiment of the present device is possible in which at least one light-emitting layer of at least one organic electroluminescent cell is formed of polymeric organic light-emitting host material selected from the group consisting of polyparaphenylene vinylene (PPV), PPV copolymers, polyanilines, poly-3-alkylthioppenes, poly-3-octylthiopenes, and polyparaphenylenes.

In another embodiment of the invention, at least one light-emitting layer of the organic electroluminescent cell of present organic light-emitting device is formed of an organic substance, containing a fluorescent dye selected from the group consisting of coumarin, dicyanomethylenepyrans and thiopyrans, polymethine, oxabenzanthracene, xanthene, pyrylium and thiapyrylium, carbostyril, and perylene fluorescent dyes.

For the effectiveness of the present organic light-emitting device, it is important that there should be no potential barriers inside the multilayer structure, which can hinder the injection of the active charge carriers into the multilayer structure. Particularly, such embodiment of the present device is possible for the increase of the electron injection, in which at least one organic electroluminescent cell additionally contains a bi-layer structure, which is formed from an organic material sublayer and a metal sublayer and this bi-layer is located between the light-emitting layer and the electron transporting layer. Then at least one organic material sublayer can be formed in contact with the organic light-emitting layer and made of an alkali fluoride for example, such as lithium fluoride, sodium fluoride, potassium fluoride, rubidium fluoride, cesium fluoride. At least one metal sublayer can be formed in contact with electron transporting layer and made of aluminum. To increase hole-injection, such embodiment of the present device is possible in which at least one organic electroluminescent cell additionally contains a hole-injection enhancement layer, which is located between the hole transporting layer and the anode. Thus, at least one hole-injection enhancement layer can be formed of either 3,4,9,10-perylenetetracarboxylic dianhydride or of bis (1,2,5,-thiadiazolo)-p-quinobis (1,3-dithiole) or of other suitable, rigid organic materials.

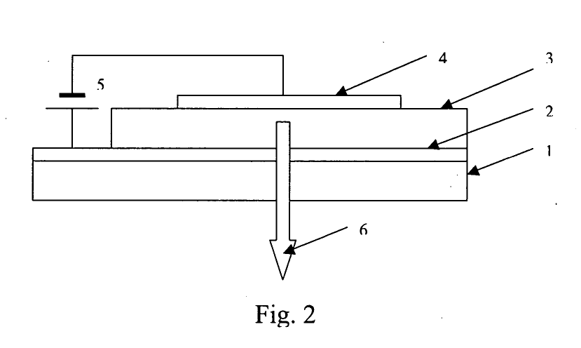

FIG. 2 schematically shows an organic light-emitting device which comprises a substrate 1 on which a first electrode (anode) 2 is formed, a light-emitting layer 3, and a second electrode (cathode) 4. The light-emitting layer 3 is formed by rodlike supramolecules, which comprise at least one polycyclic organic compound with conjugated π-system, from which is removed, at least, by one of the known methods a part of ionogenic groups while preserving the crystal structure of the layer. The anode is manufactured from ITO that is from a material with high electron work function and is used for the effective hole-injection. Such electrode is transparent. The substrate is made from a glass and also is transparent. The cathode can be made from a material with a small electron work function and is used in such OLED for the effective injection of the electrons. For example, the cathode can be made from aluminium, silver or gold or from alloys Ca/Al or Mg/Ag or Li/Al or from other suitable metals and their alloys. To the organic light-emitting device a constant voltage of displacement 5 is applied. The OLED radiates light through the transparent anode and transparent substrate. The layer 3 can be simultaneously a light-emitting and electron transporting layer. Such variant of OLED is also possible when the layer 3 simultaneously is light-emitting and hole transporting. In another embodiment, layer 3 is simultaneously both a light-emitting and an electron transporting and a hole transporting layer.

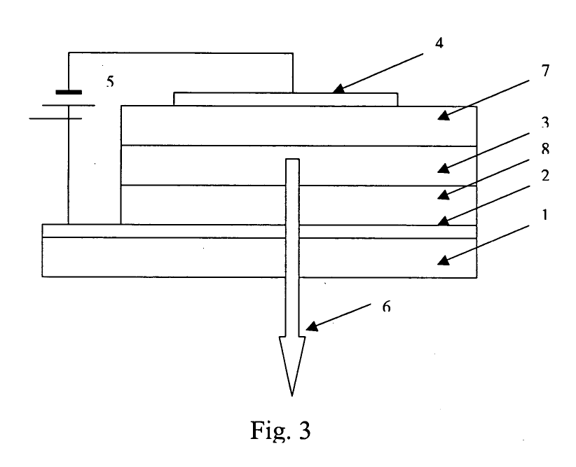

FIG. 3 schematically shows an organic light-emitting device, which additionally contains an electron transporting layer 7, located between the cathode 4 and a light-emitting layer and a hole transporting layer 8, located between the anode 2 and a light-emitting layer 3. At least, one layer in such device can be formed by rodlike supramolecules, which comprise at least one polycyclic organic compound with conjugated π-system, from which is removed, at least, by one of the known methods a part of ionogenic groups under the condition of the preservation of the crystal structure of the layer. In some examples the polycyclic organic compound is disc-shaped. In a further embodiment, at least one layer is formed with the use of at least one organic dye having in the structural formula, at least one ionogenic (hydrophilic) group, providing its solubility in polar solvents for formation of the lyotropic liquid crystal phase. In the given design of the device, it is also possible to use the layers made by using various pigments: 3,3′-dichlorobenzidine or 2,7-diaminofluorenone, or 2,6-diaminoanthraquinone, or 2,7-diaminoanthraquinone, or (p-aminophenyl) phenylamine, or tris (p-aminophenyl) amine, or 2,7-diaminodibenzothiophene sulfone, or 2,7-diaminodibenzothiophene, or 2-(p-aminophenyl)-6-aminobenzoxazole, or bis (p-aminophenyl) amine, or N-methylbis (p-aminophenyl) amine, or 2,5-bis (p-aminophenyl)-1,3,4-oxadiazole, or 1,6-diaminopyrene, or 1,5-diaminonaphthalene, or some other analogous organic compounds and their mixtures. In OLED as shown in FIG. 3, a hole transporting layer can be formed, for example, with the use of triphenylamine tetramer as the main component of the mixture and 5,6,11,12-tetraphenylnaphthacene or 9,10-diphenylanthracene as the additive in quantity 0.1-10%. Besides, in such OLED, an electron transporting layer can be formed with the use of tris-(8-quinolinato-N1, O8)-aluminum or copper phthalocyanine (CuPc) or zinc oxide (ZnO₁₋ₓ).

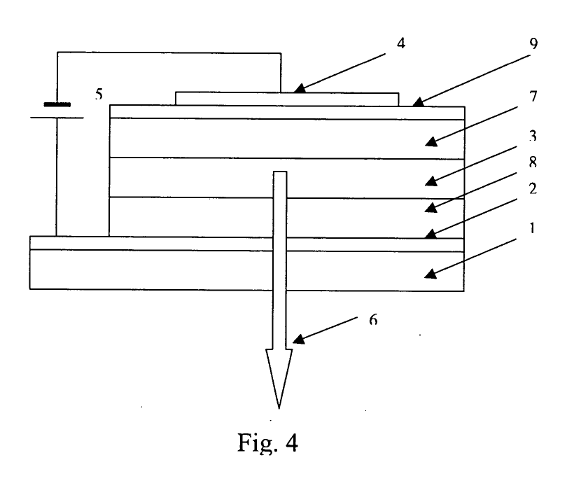

FIG. 4 schematically shows an organic light-emitting device which additionally contains a highly absorbing and low reflective layer 9, located between the cathode 4 and the electron-transporting layer 7. At least one highly absorbing and low reflective layer can be manufactured from electrically conductive materials having a work function less than 4.0 eV, and being substantially black in bulk form, for example, from calcium hexaboride (CaB₆) or/and lanthanum nitride (LaN) or/and zinc oxide (ZnO).

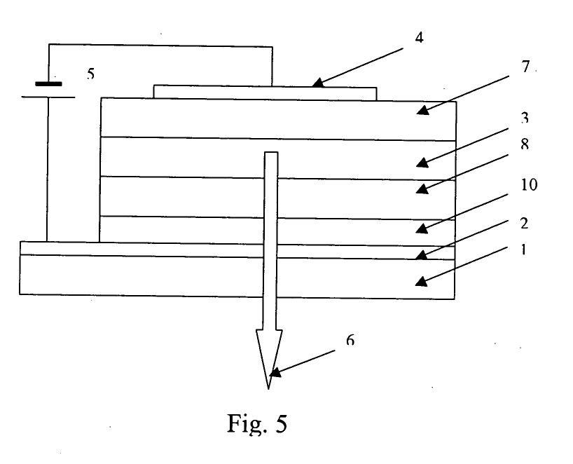

FIG. 5 schematically shows an organic light-emitting device which additionally contains an inorganic resistive layer 10, located between the anode 2 and the organic hole transporting layer 8. Such embodiment of an organic light-emitting device is possible in which, at least one inorganic resistive layer is formed either from amorphous silicon or from amorphous indium/tin oxide or from amorphous indium/zirconium oxide or from other type of thin film resistive layer which sheet resistance is between 10³ ohms/cm² and 10⁸ ohms/cm².

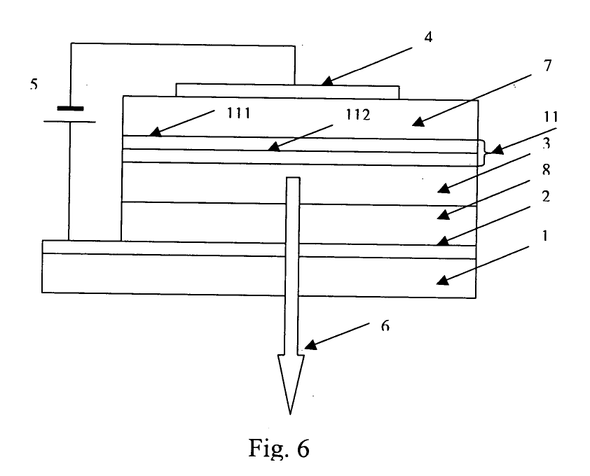

FIG. 6 schematically shows an organic light-emitting device, which additionally contains a bi-layer interfacial structure 11 which is formed from an organic material sublayer 112 and from a metal sublayer 111 and this bi-layer is located between a light-emitting layer 3 and an electron transporting layer 7. Such embodiment of an organic light-emitting device is possible in which, at least one sublayer of an organic material 112 is formed in contact with the organic light-emitting layer 3 and is formed from an alkali fluoride for example, such as lithium fluoride, sodium fluoride, potassium fluoride, rubidium fluoride, cesium fluoride. It is also possible that at least one sublayer of metal 111 is formed in contact with the electron-transporting layer and is made from aluminium.

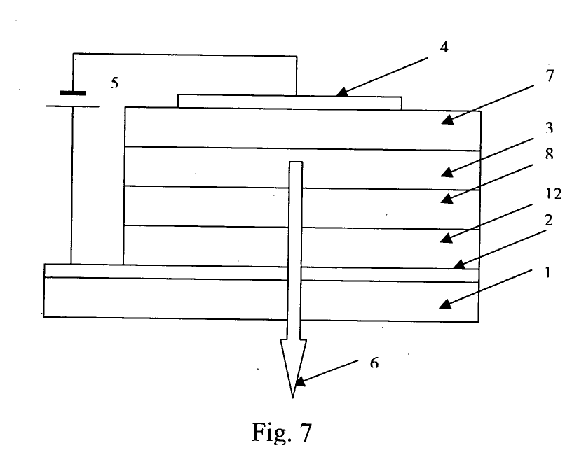

FIG. 7 schematically shows an organic light-emitting device, which additionally contains a hole injection enhancement layer 12 which is located between a hole transporting layer 8 and the anode 2. The hole injection enhancement layer can be generated either from 3,4,9,10-perylenetetracarboxylic dianhydride or from bis (1,2,5,-thiadiazolo)-p-quinobis (1,3-dithiole) or from other suitable, rigid organic materials.

### EXAMPLE

This example illustrates the preparation of the present organic light-emitting device base on a lyotropic liquid crystal formed from an organic compound, the molecules or fragments of the molecules of which have a flat structure and contain at least one ionogenic (hydrophilic) group providing the solubility of the organic substance in polar solvents for forming supramolecular complexes. As a substrate, a glass plate with a thickness of 0.5 mm was used. The substrate was covered by a thin layer of indium tin oxide (ITO) formed by the spin coating method. The thickness of the ITO layer was usually 500-800 Å. In the considered example the ITO layer was the anode. For the formation of the anode it was also possible to use other materials. It is important that this material should possess high electron work function. Another important quality of the ITO layer was its transparency. Therefore the light generated in the device traveled through the transparent ITO layer and a transparent substrate. The anisotropic crystalline layer was formed on the ITO layer. Let's consider an example of the manufacture of an anisotropic crystal layer from a lyotropic liquid crystal on the basis of an organic dye sulfo-indanthrone. This layer was used, for example, as a light-emitting layer. Light, which was generated by a light-emitting layer, depended on the used dopants. A fluorescent dye was used as a dopant selected from the group consisting of coumarin, dicyanomethylenepyrans and thiopyrans, polymethine, oxabenzanthracene, xanthene, pyrylium and thiapyrylium, carbostyril, and perylene fluorescent dyes.

A 9.5% water solution of sulfonic indanthrone was used to form a hexagonal phase at the room temperature. This dye formed supramolecular complexes of the molecules of the dye in the solution and these complexes were the basis of the crystal structure of the film. The initial paste after cleaning was applied on the ITO layer. The methods of applying the paste included spilling and smearing. Both of the method provided approximately same results for the given method.

Further influence on the lyotropic liquid crystal was carried out to decrease the viscosity of the liquid crystal for subsequent orientation. Here the solution formed a nematic phase or a mix of a nematic and hexagonal phases. The viscosity of the system decreased from 1780 mPa/cek up to 250 mPa/cek. Under the condition of the preliminary diluting influence for the decrease of the viscosity of the system, the qualitative anisotropic crystal layer was received. For the specified external diluting influence, the heating of the applied layer from the side of the substrate holder was preferred in the given example. The substrate holder was heated up to provide the temperature of the applied layer of the paste of indanthrone 56° C. However, good results were also achieved by heating the applied layer by the electromagnetic radiation, or by use of other means. The special variant of the diluting influence was the use of the heated Mayer rod for realization of the operation of the local decrease of the viscosity of a layer at the simultaneous orientation.

The following operation was the process of the orientation of the supramolecules of the lyotropic liquid crystal. For the specified external orientation influence, various orientating tools were used. In the given example the orienting cylindrical Mayer rod No. 4 with a wire twisted on it was used which determined the thickness of a wet layer of 9.5 mm. At the realization of the orienting influence, the speed of the Mayer rod moving was 13 mm/sec. The shift strains arising during the Mayer rod's influence resulted in additional reduction of the viscosity of the system.

After the orientation, the heating of the substrate holder was stopped or the heated Mayer rod was removed.

The following operation of the formation of an anisotropic crystal layer was drying. Preferably the solvent was removed slowly so that the earlier orientated structure of the layer was not disturbed. In the described example the drying was carried out at the room temperature and the humidity of 60%.

As the result the anisotropic crystalline layer with the thickness 0.3-0.4 microns having a high degree of the anisotropy of properties was achieved: the dichroic ratio was Kd=28 at the admission T=40% (while for the traditional method Kd did not exceed 20), with a good reproducibility of the parameters, both on the surface of a layer, and from a group to a group. Perfection of the crystal structure of the result anisotropic crystalline layers was estimated by optical methods and x-ray diffractometry. The x-ray analysis of the anisotropic crystalline layers showed that as the result of the carried out technological operations the formed layer had an interplanar spacing of 3.4±0.3 Å in the direction of one of the optical axes.

The external influence was applied to the formed anisotropic crystal layer, with the purpose of removal from it ionogenic groups at the preservation of the crystal structure of a layer after the termination of the external influence, and the duration in time, the character and the intensity of this external influence were selected so as to provide the removal from an anisotropic crystal layer of a part of all ionogenic groups at the preservation of the crystal structure of a layer. In the initial organic substance, both sulfo-groups and any other ionogenic (hydrophilic) groups (for example, COO⁻, PO₄⁻, cation groups, carboxy-groups and others) which provided amphiphilic properties to the initial organic substances were used. The external influence on an anisotropic crystal layer is local heating of the anisotropic crystalline layer to a pyrolysis temperature. This temperature was determined by experiments for each organic material. In the considered example, the pyrolysis temperature was approximately 350° C. The heating of an anisotropic crystalline layer was carried out by a source of heat located on the part of a substrate. The thermal external influence on the anisotropic crystalline layer proceeded in 10 minutes in the atmosphere of nitrogen. The area of the local external influence represented a circle with the diameter of 1 cm. The other version of the external influence was the treatment on, at least part of an anisotropic crystalline layer by the high-frequency and/or laser radiation which frequency was in the resonance with, at least, one absorption band of the organic compound. As the result of the external influence, the treated part of the anisotropic crystalline layer became insoluble in polar solvents. Then the anisotropic layer treated was covered with a mask-layer with the openings above the areas of a layer with the removed ionic groups, and the material of a mask was dissolved in polar solvents. Through the openings in a mask getting the metal dust on the top contact—the cathode was carried out. Aluminum was used as the metal. The thickness of this layer was approximately 50 Å-100 Å. In this example the thickness of this layer was selected so that the metal covering served as a reflector with the factor of reflection not less than 95% for the light generated in the device. Further the manufactured multilayer structure was washed out in the polar solvent, for example, in the water. During the washing the mask layer was removed. The metal layer which was formed on the mask layer was also removed. Finally, the anisotropic crystalline layer was removed, which was not subjected to the external influence and from which ionogenic groups were not removed. As the result of the described technological operations, the organic light-emitting device was formed with the top contact-cathode made from metal, and the bottom contact-anode made from ITO. The positive displacement voltage was applied to the result device, thus the cathode injected electrons into the anisotropic crystal layer, and the anode injected holes. Under the action of the applied voltage, the injected active charge-carriers drifted towards each other and recombine in the anisotropic crystalline layer with the emission of light quantums.

In one embodiment of the invention the substrate and the electrode closest to the substrate are transparent. In the other embodiment of the invention the substrate is substantially opaque and the electrode most distant from the substrate is transparent.

As described above, a backlight polar organic light-emitting device has been described. The foregoing descriptions of specific embodiments of the invention have been presented for the purpose of illustration and description. They are not intended to be exhaustive or to limit the invention to the precise forms disclosed, and obviously many modifications, embodiments, and variations are possible in light of the above teaching. It is intended that the scope of the invention be defined by the claims appended hereto and their equivalents.

What is claimed is:

1. A method of making an anisotropic electrically conducting layer, which has a globally ordered crystalline structure, the method comprising:
forming an anisotropic crystalline layer by means of Cascade Crystallization Process, wherein said anisotropic crystalline layer is characterized by the globally ordered crystalline structure with the intermolecular spacing of 3.4±0.3 Å along the polarization axis of said layer, and formed by rodlike supramolecules, which comprise at least one polycyclic organic compound with conjugated π-system and ionogenic groups; and
applying an external influence upon the anisotropic crystalline layer to remove the ionogenic group from the anisotropic crystalline layer,
wherein the duration, character and intensity of the external influence are selected so as to ensure a partial removal of part of the ionogenic groups from the anisotropic crystalline layer while retaining a crystalline structure after termination of the external influence.

2. The method according to claim 1, wherein the external influence is applied by a local or complete heating of the anisotropic crystalline layer to a pyrolysis temperature.

3. The method according to claim 2, wherein the heating is conducted by one or several means selected from the group consisting of microwave radiation, concentric electrical heaters, resistive heaters, an alternative electric field, and alternative magnetic field, and a flow of heated liquid and/or gas.

4. The method according to claim 1, wherein the external influence is applied by treating at least part of the anisotropic crystalline layer by microwave and/or laser radiation having a frequency in resonance with at least an absorption band of the organic compound.

5. The method according to claim 1, wherein the ionogenic groups are selected from the group consisting of sulfonic groups, COO⁻, PO4⁻, cation groups, and carboxy groups which are ionogenic groups used for imparting amphiphilic properties to the organic compound.

6. The method according to claim 1, wherein at least one anisotropic crystalline layer is formed on a substrate.

7. The method according to claim 6, wherein the substrate has a flat, convex or concave surface.

8. The method according to claim 6, wherein the external influence is applied by heating up the substrate.

9. The method according to claim 1 or 6, wherein first at least one layer of an additional electrically conducting material is formed on the substrate and further the anisotropic crystalline layer is formed on said additional electrically conducting layer.

10. The method according to claim 1 or 6, wherein first at least one said anisotropic electrically conducting layer is formed on the substrate and further the anisotropic crystalline layer is formed on the top of the anisotropic electrically conducting layer.

11. The method according to claim 1, wherein the external influence is applied in an atmosphere of buffer gas.

12. The method according to claim 11, wherein the buffer gas comprises He, Ar, Xe and any other inert gas, N₂, CO₂, and any other non-reactive gas.

13. The method according to claim 1, wherein the organic compound further comprises at least one dopant substance and/or a compound which does not break the flat structure of the molecules or fragments of the molecules of the lyotropic liquid crystal organic. compound and changes the type and size of the electrical conductivity of the anisotropic electrically conductive layer.

14. The method according to claim 1, wherein the organic compound further comprises at least one dopant substance and/or compound which does not break the flat structure of the molecules or fragments of the molecules of the lyotropic liquid crystal organic compound and creates centers of an emitting electron-hole recombination with emission of quanta of light in one or several of the spectral regions including infra-red, visible and ultra-violet spectral regions.

15. The method according to claim 1, wherein the organic compound used for preparing a lyotropic liquid crystal comprises at least one aromatic compound with the general structural formula
{K}(M)n,
where K is a dye, the structure of which contains one or more ionogenic groups, either same or different, ensuring the solubility in polar solvents for the formation of a lyotropic liquid crystal phase; M is a counterion; and n is the number of counterions in the dye molecule, which can be fractional if the counterion is shared among several molecules.

16. An organic light-emitting device, comprising:
a substrate; and
an organic electroluminescent cell formed on the substrate,
wherein said organic electroluminescent cell comprises:
a first electrode that serves as an anode;
a second electrode that serves as a cathode; and
at least one light-emitting layer located between the anode and cathode,
wherein the at least one of the light-emitting layers is an anisotropic electrically conducting layer, which has a globally ordered crystalline structure with an intermolecular spacing of 3.4±0.3 Å in along the polarization axis of said layer, is formed by rodlike supramolecules, which comprise at least one polycyclic organic compound with conjugated π-system and ionogenic groups.

17. The organic light-emitting device according to claim 16, wherein at least one layer of the organic electroluminescent cell is simultaneously electron transporting and light-emitting.

18. The organic light-emitting device according to claim 16, wherein at least one layer of the organic electroluminescent cell is simultaneously hole transporting and light emitting.

19. The organic light-emitting device according to claim 16, wherein at least one layer of the organic electroluminescent cell is simultaneously light-emitting and both electron- and hole transporting.

20. The organic light-emitting device according to claim 16, wherein the organic electroluminescent cell further comprises an electron transporting layer located between the cathode and the light-emitting layer and/or at least one hole transporting layer located between the anode and the light-emitting layer.

21. The organic light-emitting devices according to claim 16, wherein at least one light-emitting layer of the organic electroluminescent cell is formed using one of organic compounds selected from the group consisting of indanthrone (Vat Blue 4), or 1,4,5,8-naphtalene tetracarboxylic (PTCDA), bis-(1,2,5-thiadiazolo)-p-quinobis-(1,3-dithiol) (BTQBT), aluminum dibenzoimidazol (Vat Red 14), 3,4,9,10-pyrylentetracarboxylic dibenzoimidazol, or hinakridon (Pigment Violet 19), and 3,4,9,10-pyrylenetetracarboxylic dianhydride tris (8-hydroxyquinoline) (Alq3).

22. The organic light-emitting device according to claim 16 wherein at least one light-emitting layer of the organic electroluminescent cell is formed using at least one phthalocyanine selected from the group consisting of metal-free phthalocyanines (H₂Pc), phthalocyanines with monovalent or divalent metal, phthalocyanines with metal halide or metal hydroxide, phthalocyanines with tetravalent metals, and phthalocyanines, in which the central ion of metal is replaced or which are substituted by sulfonic acid (or amide), carboxylic acid, alkyl, aryl, halide, or nitro.

23. The organic light-emitting device according to claim 16, wherein at least one light-emitting layer of the organic electroluminescent cell is formed using at least one organic compound or their mixtures selected from the group consisting of different pigments, 3,3′-dichlorobenzidine, 2,7-diaminofluorenone, 2,6-diaminoanthraquinone, 2,7-diaminoanthraquinone, (p-aminophenyl) phenylamine, tris (p-aminophenyl) amine, 2,7-diaminodibenzothiophene sulfone, 2,7-diaminodibenzothiophene, 2-(p-aminophenyl)-6-aminobenzoxazole, bis (p-aminophenyl) amine, N-methylbis (p-aminophenyl) amine, 2,5-bis (p-aminophenyl)-1,3,4-oxadiazole, 1,6-diaminopyrene, and 1,5-diaminonaphthalene.

24. The organic light-emitting device according to claim 20, wherein at least one hole transporting layer of the organic electroluminescent cell is formed using a mixture of triphenylamine tetramer and 0.1-10% solution of 5,6,11,12-tetraphenylnaphthacene or of 9,10-diphenylanthracene.

25. The organic light-emitting device according to claim 20, wherein at least one hole transporting layer of the organic electroluminescent cell is formed using 4,4′-bis-[(1-naphthyl)-N-phenylamino]-bi-phenyl or N,N′-diphenyl-N,N′-bis (3-methylpheny) 1-1′biphenyl-4,4′diamine.

26. The organic light-emitting device according to claim 20, wherein the at least one hole transporting layer of the organic electroluminescent cell is made from a material selected from the group of aromatic tertiary amines.

27. The organic light-emitting device according to claim 16, wherein the cathode is made of a material with a small work function of electrons.

28. The organic light-emitting device according to claim 27, wherein the cathode is nontransparent and made of any material of the list including aluminum, silver, gold, and alloys of Ca/Al, Mg/Ag and Li/Al.

29. The organic light-emitting device according to claim 16, wherein the anode is made of a material with large work function of electrons.

30. The organic light-emitting device according to claim 29, wherein the anode is transparent and made of ITO.

31. The organic light-emitting device according to claim 16, wherein the substrate is transparent or nontransparent, hard or flexible, made of any material selected from the group consisting of glass, quartz, plastic, metal and semiconductor.

32. The organic light-emitting device according to claim 16, wherein the substrate has a flat, convex or concave surface.

33. The organic light-emitting device according to claim 16, wherein the substrate has anisotropic properties, at least on part of the surface, which are caused by either chemical bonds, or the relief or the texture formed on the surface of the substrate either from the material of the substrate itself or from the material, applied on the surface of the substrate.

34. The organic light-emitting device according to claim 16, wherein the substrate is made of any material selected from the group consisting of aluminum, cobalt, copper, molybdenum, nickel, platinum, tantalum, and their alloys.

35. The organic light-emitting device according to claim 16, wherein the substrate is made of any material selected from the group consisting of polymeric material, glass, metal, ceramics, metal ceramics, and any combination thereof.

36. The organic light-emitting device according to claim 20, wherein the organic electroluminescent cell further comprises a highly absorbing and low reflective layer located between the cathode and the electron transporting layer.

37. The organic light-emitting device according to claim 36, wherein the highly absorbing and low reflective layer is made of electrically conductive materials having a work function less than 4.0 eV, and substantially black in bulk form and made of any one or several materials selected from the group consisting of calcium hexaboride (CaB₆), lanthanum nitride (LaN), and zinc oxide (ZnO).

38. The organic light-emitting device according to claim 20, wherein the organic electroluminescent cell further comprises an inorganic resistive layer located between the anode and the hole transporting layer.

39. The organic light-emitting device according to claim 38, wherein the inorganic resistive layer is formed of a material selected from the group consisting of amorphous silicon, amorphous indium/tin oxide, amorphous indium/zirconium oxide, and a thin film resistive layer having a sheet resistance between 10³ ohms/cm² to 10⁸ ohms/cm².

40. The organic light-emitting device according to claim 16, wherein at least one light-emitting layer of the organic electroluminescent cell is formed of polymeric organic light-emitting host material selected from the group consisting of polyparaphenylene vinylene (PPV), PPV copolymers, polyanilines, poly-3-alkylthioppenes, poly-3-octylthiopenes, and polyparaphenylenes.

41. The organic light-emitting device according to claim 40, wherein at least one light-emitting layer of the organic electroluminescent cell is formed of an organic substance comprising a fluorescent dye selected from the group consisting of coumarin, dicyanomethylenepyrans, thiopyrans, polymethine, oxabenzanthracene, xanthene, pyrylium and thiapyrylium, carbostyril, and perylene fluorescent dyes.

42. The organic light-emitting device according to claim 20, wherein the organic electroluminescent cell further comprises a bi-layer structure, which is formed from an organic material sublayer and a metal sublayer and said bi-layer structure is located between the light-emitting layer and the electron transporting layer.

43. The organic light-emitting device according to claim 42, wherein the organic material sublayer is formed in contact with the organic light-emitting layer and is made of any material selected from the group consisting of an alkali fluoride, lithium fluoride, sodium fluoride, potassium fluoride, rubidium fluoride, and cesium fluoride.

44. The organic light-emitting device according to claim 42, wherein the metal sublayer is made of aluminum and formed in contact with the electron transporting layer.

45. The organic light-emitting device according to claim 20, wherein at least one organic electroluminescent cell further comprises a hole-injection enhancement layer located between the hole transporting layer and the anode.

46. The organic light-emitting device according to claim 45, wherein the hole-injection enhancement layer is formed of 3,4,9,10-perylenetetracarboxylic dianhydride or bis (1,2,5,-thiadiazolo)-p-quinobis (1,3-dithiole).

47. The organic light-emitting device according to claim 16, wherein the substrate and the electrode closest to said substrate are transparent.

48. The organic light-emitting device according to claim 16, wherein the substrate is substantially opaque and the electrode the most distant from said substrate is transparent.
